(19) United States
(12) Patent Application Publication
(10) Pub. No.: US 2019/0218140 A1
(43) Pub. Date: Jul. 18, 2019

(54) SUBSTRATE PROVIDED WITH A STACK HAVING THERMAL PROPERTIES COMPRISING AT LEAST ONE LAYER COMPRISING SILICON-ZIRCONIUM NITRIDE ENRICHED IN ZIRCONIUM, ITS USE AND ITS MANUFACTURE

(71) Applicant: SAINT-GOBAIN GLASS FRANCE, Courbevoie (FR)

(72) Inventors: Nicolas MERCADIER, Paris (FR); Matthieu ORVEN, Gennevilliers (FR); Xavier CAILLET, Fontenay Sous Bois (FR); Dominique BILLIERES, Saint-Saturnin Les Avignon (FR)

(73) Assignee: SAINT-GOBAIN GLASS FRANCE, Courbevoie (FR)

(21) Appl. No.: 16/318,968

(22) PCT Filed: Aug. 2, 2017
(86) PCT No.: PCT/FR2017/052166

§ 371 Date: Jan. 18, 2019

(30) Foreign Application Priority Data
Aug. 2, 2016 (FR) 1657497

(51) Int. Cl. C03C 17/36; G02B 1/11

(52) U.S. Cl. CPC C03C 17/366; G02B 1/11; C03C 17/3626; G02F 1/155; C03C 17/3644; C03C 17/3649; C03C 17/3681; C03C 17/3642

(57) ABSTRACT

A transparent substrate is provided on a main face with a stack of thin layers including a single metallic functional layer having properties of reflection in the infrared region and/or in the solar radiation region, in particular based on silver or on silver-containing metal alloy, and two antireflective coatings. The antireflective coatings each include at least one dielectric layer. The functional layer is positioned between the two antireflective coatings. At least the antireflective coating located between the substrate and the functional layer, indeed even both antireflective coatings, include(s) a layer including silicon-zirconium nitride, SiₓZr_{y}N_{z}, with an atomic ratio of Zr to the sum Si+Zr, y/(x+y), which is between 25.0% and 40.0%, these values being incorporated, indeed even between 27.0% and 37.0%, these values being incorporated.

The invention relates to a transparent substrate in particular made of a rigid mineral material, such as glass, said substrate being coated with a stack of thin layers comprising a functional layer of metallic type which can influence solar radiation and/or long wavelength infrared radiation.

The invention more particularly relates to the use of such substrates for manufacturing thermal insulation and/or solar protection glazings. These glazings may be intended to equip both buildings and vehicles, in particular with a view to reducing the air-conditioning load and/or preventing excessive overheating (“solar control” glazings) and/or reducing the amount of energy dissipated toward the outside (“low-e” glazings) driven by the ever increasing importance of glazed surfaces in buildings and vehicle compartments.

These glazings can furthermore be incorporated in glazings having specific functionalities, such as, for example, heated glazings or electrochromic glazings.

One type of stack of layers known for conferring such properties on substrates comprises a metallic functional layer having properties of reflection in the infrared region and/or in the solar radiation region, in particular a metallic functional layer based on silver or on a silver-containing metal alloy.

In this type of stack, the functional layer is thus positioned between two antireflective coatings each generally comprising several layers which are each made of a dielectric material of the nitride type, in particular silicon nitride or aluminum nitride, or of the oxide type. From the optical viewpoint, the aim of these coatings, which frame the metallic functional layer, is to render this metallic functional layer “anti reflective”.

A blocker coating is, however, sometimes inserted between one or each antireflective coating and the metallic functional layer: a blocker coating positioned under the functional layer in the direction of the substrate and/or a blocker coating positioned on the functional layer on the opposite side from the substrate.

It is known, for example from the European patent application No. EP 718 250, that a “wetting” dielectric layer based on zinc oxide positioned directly under a silver-based metallic functional layer, in the direction of the carrying substrate, promotes the achieving of an appropriate crystallographic state of the metallic functional layer while exhibiting the advantage of being able to withstand a high-temperature bending or tempering heat treatment.

Furthermore, this document discloses the favorable effect of the presence of a layer deposited in the metallic form directly on and in contact with the silver-based functional layer for the protection of the functional layer during the deposition of the other layers on top and during a high-temperature heat treatment. A person skilled in the art knows this type of layer under the generic term of “blocker layer” or “blocker”.

This document discloses especially that the presence of a barrier layer, for example comprising silicon nitride, in each of the antireflective coatings, one below the wetting layer in the direction of the substrate and the other above the blocker layer, makes it possible to produce a stack which resists well a bending or tempering heat treatment.

One aim of the invention is to improve the prior art by developing a novel type of stack of layers being mono-functional-layer, which exhibits a low sheet resistance (and thus a reduced emissivity) but also a high luminous transmission and a high solar factor, this being the case optionally after one (or more) high-temperature bending and/or tempering and/or annealing heat treatment(s).

One aim of the invention is furthermore for the stack to exhibit a favorable colorimetry, this being the case optionally after one (or more) high-temperature bending and/or tempering and/or annealing heat treatment(s), and in particular a color in reflection on the stack side which is not too red and/or a color in transmission which is not too yellow.

It has been discovered that, surprisingly, the presence of a layer comprising silicon-zirconium nitride with a certain atomic proportion of zirconium by the assembly formed by the silicon and the zirconium, in such a stack, had very favorable effects on the achieving of a higher solar factor, this being the case both in the double glazing configuration and in the triple glazing configuration, and on the achieving of such a colorimetry.

A subject-matter of the invention is thus, in its broadest sense, a transparent substrate as claimed in claim 1. The dependent claim's exhibit advantageous alternative forms.

The transparent substrate is thus provided on a main face with a stack of thin layers comprising a single metallic functional layer having properties of reflection in the infrared region and/or in the solar radiation region, in particular based on silver or on a silver-containing metal alloy, and two antireflective coatings, said antireflective coatings each comprising at least one dielectric layer, said functional layer being positioned between the two antireflective coatings. This substrate is noteworthy in that at least the antireflective coating located between said substrate and said functional layer, indeed even both antireflective coatings, comprise(s) a layer comprising silicon-zirconium nitride, SiₓZr_{y}N_{z}, with an atomic ratio of Zr to the sum Si+Zr, y/(x+y), which is between 25.0% and 40.0%, these values being incorporated.

A particularly appropriate range of atomic ratio of Zr to the sum Si+Zr, y/(x+y), is between 26.32% and 37.5%, these values being incorporated. This material can be deposited with a target comprising from 70.0 atom % to 60.0 atom % of Si per 25.0 atom % to 36.0 atom % of Zr; this target being sputtered in a nitrogen-containing atmosphere.

Another particularly appropriate range of atomic ratio of Zr to the sum Si+Zr, y/(x+y), is between 27.0% and 37.0%, these values being incorporated.

It is possible for said layer comprising silicon-zirconium nitride, SiₓZr_{y}N_{z}, indeed even for each layer comprising silicon-zirconium nitride, SiₓZr_{y}N_{z}, to comprise an atomic ratio of Zr to the sum Si+Zr which is between 26.0% and 30.0%, these values being incorporated, or between 31.0% and 38.0%, these values being incorporated, or between 25.5% and 32.5%, these values being incorporated.

The antireflective coating located between said substrate and said functional layer can be the only one of the two antireflective coatings to comprise a layer comprising silicon-zirconium nitride, SiₓZr_{y}N_{z}, and optionally it can comprise a single layer comprising silicon-zirconium nitride, SiₓZr_{y}N_{z}, with an atomic ratio of Zr to the sum Si+Zr, y/(x+y), which is between 25.0% and 40.0%, these values being incorporated, indeed even between 27.0% and 37.0%, these values being incorporated.

In the case where the stack comprises several layers comprising silicon-zirconium nitride, SiₓZr_{y}N_{z}, then the atomic ratio of Zr to the sum Si+Zr, y/(x+y), for each of these layers is preferably between 25.0% and 40.0%, these values being incorporated, indeed even for each of these layers is between 27.0% and 37.0%, these values being incorporated, but it is not necessarily the same for all these layers comprising silicon-zirconium nitride, SiₓZr_{y}N_{z}.

It is possible for the ratio y/(x+y) to be different for two layers comprising silicon-zirconium nitride, SiₓZr_{y}N_{z}, of said stack.

In the case where each of the two antireflective coatings comprises a layer comprising silicon-zirconium nitride, SiₓZr_{y}N_{z}, they can optionally each comprise a single layer comprising silicon-zirconium nitride, SiₓZr_{y}N_{z}, with an atomic ratio of Zr to the sum Si+Zr, y/(x+y), which is between 25.0% and 40.0%, these values being incorporated, indeed even between 27.0% and 37.0%, these values being incorporated, or between 26.0% and 30.0%, these values being incorporated, or between 31.0% and 38.0%, these values being incorporated, or between 25.5% and 32.5%, these values being incorporated.

A particularly appropriate range of atomic ratio of Zr to the sum Al+Si+Zr, y/(w+x+y), is between 25.0% and 36.0%, these values being incorporated. This material can be deposited with a target comprising from 70.0 atom % to 60.0 atom % of Si per 25.0 atom % to 36.0 atom % of Zr with 5.0 atom % of Al in all cases; this target being sputtered in a nitrogen-containing atmosphere.

“Transparent substrate” within the meaning of the present invention should be understood as meaning that the substrate is not opaque and that it would exhibit, without the stack, a luminous transmission of at least 5%.

“Coating” within the meaning of the present invention should be understood as meaning that there may be a single layer or several layers of different materials within the coating.

“In contact” is understood to mean, within the meaning of the invention, that no layer is interposed between the two layers under consideration.

“Based on” is understood to mean, within the meaning of the invention, that the element or the material thus denoted is present at more than 50 atom % in the layer under consideration.

Furthermore, in the present document, all the refractive indices are indicated with respect to a wavelength of 550 nm; the optical thicknesses of the layers are the product of the physical thickness of this layer by this refractive index at this wavelength and the optical thicknesses of the coating are the sum of the optical thicknesses of all the dielectric layers of the coating; by default, if the physical/optical distinction is not indicated for a thickness, this is a physical thickness.

In the present document, the dielectric layers can be differentiated into three categories:
low-index layers, the refractive index of which is n<1.95
medium-index layers, the refractive index of which is 1.95 n<2.10
high-index layers, the refractive index of which is n>2.10.

Advantageously, the single metallic functional layer having properties of reflection in the infrared region and/or in the solar radiation region is a continuous layer.

Advantageously, the stack according to the invention does not comprise a layer comprising titanium oxide; titanium dioxide, TiO₂, exhibits a very high refractive index and this index may be too high for the targeted applications. Substoichiometric titanium oxide, TiO_{b} with b which is a number below 2, can constitute a high-index layer but its refractive index is a function of its oxidation and its oxidation is difficult to control industrially; the stack according to the invention is thus easier to manufacture industrially.

Preferably, said layer comprising silicon-zirconium nitride, SiₓZr_{y}N_{z}, of the stack according to the invention, or each of the layers comprising silicon-zirconium nitride of the stack according to the invention, does not comprise titanium.

Preferably, said layer comprising silicon-zirconium nitride, SiₓZr_{y}N_{z}, of the stack according to the invention is made of silicon-zirconium nitride, SiₓZr_{y}N_{z}, or is made of silicon-zirconium nitride doped with aluminum, SiₓZr_{y}N_{z}:Al.

Preferably, said layer comprising silicon-zirconium nitride, SiₓZr_{y}N_{z}, exhibits a nitridation z of between 4/3(x+y) and 5/3(x+y), these values being incorporated; preferably again, each layer comprising silicon-zirconium nitride, SiₓZr_{y}N_{z}, exhibits a nitridation z of between 4/3(x+y) and 5/3(x+y), these values being incorporated.

Preferably, furthermore, said layer comprising silicon-zirconium nitride of said stack, or each of the layers comprising silicon-zirconium nitride of said stack, does not comprise deliberately introduced oxygen. The presence of oxygen in the layer or layers comprising silicon-zirconium nitride, SiₓZr_{y}N_{z}, is to be avoided as this results in a decrease in the refractive index of the layer. The fact that this layer does not comprise oxygen should be understood as meaning that there is no oxygen in a significant amount with respect to the nitrogen, that is to say in a relative amount of at least 5 atom % with respect to the total amount of nitrogen and oxygen, it being known that the affinity of the elements Si and Zr is greater for oxygen than for nitrogen.

In a specific alternative form, the antireflective coating located between said substrate and said functional layer additionally comprises a layer comprising zirconium-free silicon nitride, said layer comprising zirconium-free silicon nitride preferably being located between said substrate and said layer comprising silicon-zirconium nitride, SiₓZr_{y}N_{z}, and more preferably both directly on said main face of the substrate and directly under said layer comprising silicon-zirconium nitride, SiₓZr_{y}N_{z}.

Preferably then, said layer of the antireflective coating located between said substrate and said functional layer and comprising zirconium-free silicon nitride exhibits a thickness of between 5.0 and 25.0 nm, these values being included, indeed even between 15.0 and 20.0 nm, these values being included.

In another specific alternative form, which can optionally be combined with the preceding one, the antireflective coating located above said functional layer on the opposite side from said substrate additionally comprises a layer comprising zirconium-free silicon nitride, said layer comprising zirconium-free silicon nitride preferably being located above said layer comprising silicon-zirconium nitride, SiₓZr_{y}N_{z}.

Preferably then, said layer of the antireflective coating located above said functional layer and comprising zirconium-free silicon nitride exhibits a thickness of between 25.0 and 35.0 nm, these values being included.

These solutions make it possible reduce the cost as the zirconium-free silicon nitride is less expensive than the silicon-zirconium nitride.

In a specific alternative form, the antireflective coating located above said functional layer and on the opposite side from said substrate additionally comprises a layer made of a dielectric material having a low index, in particular based on silicon oxide. The material of this layer can consist solely of Si and O; it can in particular be silicon dioxide or silicon dioxide doped with aluminum. This layer made of a dielectric material having a low index is preferably the final dielectric layer of the antireflective coating located above said functional layer.

The material of this low-index dielectric layer preferably exhibits an index of between 1.60 and 1.80; the layer preferably exhibits a thickness of between 15.0 and 60.0 nm, indeed even between 20.0 and 58.0 nm, indeed even between 30.0 and 55.0 nm.

A layer based on zinc oxide can be located below and in contact with said functional layer. This has the effect of actively participating in the obtaining of a metallic functional layer exhibiting a high degree of crystallization and thus a low sheet resistance and thus a low emissivity.

Preferably, said layer comprising silicon-zirconium nitride, SiₓZr_{y}N_{z}, which is located between said substrate and said functional layer, exhibits a thickness of between 10.0 and 30.0 nm, these values being included.

Preferably, furthermore, said layer comprising silicon-zirconium nitride, SiₓZr_{y}N_{z}, which is located above said functional layer on the opposite side from said substrate, exhibits a thickness of between 6.0 and 12.0 nm, these values being included.

Preferably, the stack does not comprise any layer comprising silicon-zirconium nitride, SiₓZr_{y}N_{z}, which would not be with an atomic ratio of Zr to the sum Si+Zr, y/(x+y), which is between 25.0% and 40.0%.

The stack can thus comprise a final layer (overcoat), that is to say a protective layer. This protective layer preferably exhibits a physical thickness of between 0.5 and 10.0 nm.

The glazing according to the invention incorporates at least the substrate carrying the stack according to the invention, optionally in combination with at least one other substrate. Each substrate can be clear or tinted. One of the substrates at least in particular can be made of bulk-tinted glass. The choice of coloration type will depend on the level of luminous transmission and/or on the colorimetric appearance which are desired for the glazing once its manufacture has been completed.

The glazing according to the invention can exhibit a laminated structure, combining in particular at least two rigid substrates of the glass type by means of at least one sheet of thermoplastic polymer, in order to exhibit a structure of glass/stack of thin layers/sheet(s)/glass type. The polymer can in particular be based on polyvinyl butyral PVB, ethylene/vinyl acetate EVA, polyethylene terephthalate PET or polyvinyl chloride PVC.

The glazing can furthermore exhibit a structure of glass/stack of thin layers/polymer sheet(s) type.

The glazings according to the invention are capable of being subjected to a heat treatment without damage to the stack of thin layers. They are thus optionally bent and/or tempered.

The glazing can be bent and/or tempered while consisting of a single substrate, that provided with the stack. It is then a “monolithic” glazing. In the case where they are bent, in particular for the purpose of forming glazings for vehicles, the stack of thin layers is preferably found on a face which is at least partially nonplanar.

The glazing can also be a multiple glazing, in particular a double glazing, it being possible for at least the substrate carrying the stack to be bent and/or tempered. It is preferable in a multiple glazing configuration for the stack to be positioned so as to face the inserted gas-filled cavity. In a laminated structure, the stack can be in contact with the polymer sheet.

The glazing can also be a triple glazing consisting of three glass sheets separated in pairs by a gas-filled cavity. In a triple glazing structure, the substrate carrying the stack can be on face 2 and/or on face 5, when it is considered that the incident direction of the sunlight traverses the faces in increasing order of their number.

When the glazing is monolithic or multiple, of the double glazing, triple glazing or laminated glazing type, at least the substrate carrying the stack can be made of bent or tempered glass, it being possible for this substrate to be bent or tempered before or after the deposition of the stack.

The present invention furthermore relates to a process of the manufacture of the substrate according to the invention, in which said layer comprising silicon-zirconium nitride, SiₓZr_{y}N_{z}, is manufactured by sputtering, in a nitrogen-comprising atmosphere, a target comprising an atomic ratio of Zr to the sum Si+Zr, y/(x+y), which is between 25.0% and 40.0%, these values being incorporated, indeed even 26.32% and 37.5%, these values being incorporated, indeed even between 27.0% and 37.0%, these values being incorporated.

Preferably, said atmosphere does not comprise oxygen. The fact that this atmosphere does not comprise oxygen should be understood as meaning that there is no oxygen deliberately introduced into the sputtering atmosphere of said target.

The present invention furthermore relates to a target for the implementation of the process according to the invention, said target comprising an atomic ratio of Zr to the sum Si+Zr, y/(x+y), which is between 25.0% and 40.0%, these values being incorporated, indeed even 26.32% and 37.5%, these values being incorporated, indeed even between 27.0% and 37.0%, these values being incorporated.

Advantageously, the present invention thus makes it possible to produce a stack of thin layers being mono-metallic-functional-layer which exhibits a greater solar factor and a satisfactory colorimetric appearance, in particular after bending or temping heat treatment.

The details and advantageous characteristics of the invention emerge from the following nonlimiting examples, illustrated by means of the appended figures which illustrate:

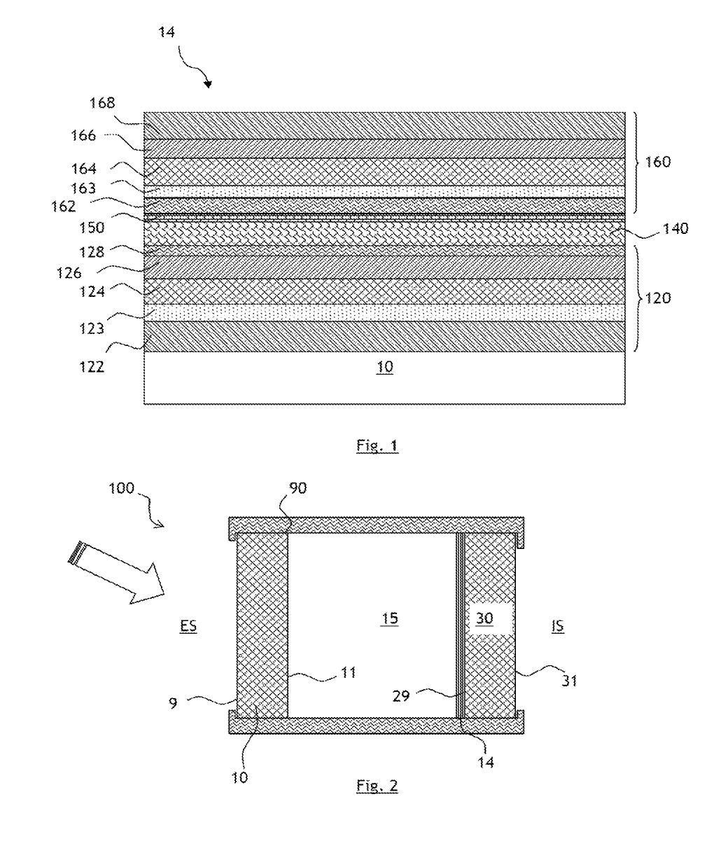

in FIG. 1, a functional monolayer stack, the functional layer being deposited directly under an overblocker coating;

in FIG. 2, a double glazing solution incorporating a functional monolayer stack;

in FIG. 3, the curve of refractive index, at 550 nm, of silicon-zirconium nitride (“SiZr”) as a function of the content of Zr with respect to the sum of Zr+Si, and also the refractive index, at 550 nm, of titanium dioxide TiO₂; and

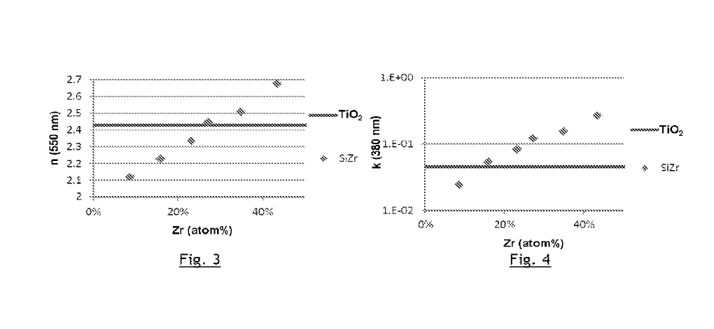

in FIG. 4, the curve of the coefficient of absorption, at 380 nm, of silicon-zirconium nitride (“SiZr”) as a function of the content of Zr with respect to the sum of Zr+Si, and also the coefficient of absorption, at 380 nm, of titanium dioxide TiO₂.

In FIGS. 1 and 2, the proportions between the thicknesses of the different layers or of the different elements are not respected in order to make them easier to read.

FIG. 1 illustrates a structure of a mono-functional-layer stack 14 according to the invention deposited on a face 29 of a transparent glass substrate 30, in which the single functional layer 140, in particular based on silver or on a silver-containing metal alloy, is positioned between two antireflective coatings, the underlying antireflective coating 120 located under the functional layer 140 in the direction of the substrate 30 and the overlying antireflective coating 160 positioned above the functional layer 140 on the opposite side from the substrate 30.

These two antireflective coatings 120, 160, each comprise at least one dielectric layer 122, 123, 124, 126, 128; 162, 163, 164, 166, 168.

Optionally, on the one hand, the functional layer 140 can be deposited directly on an underblocker coating (not illustrated) positioned between the underlying antireflective coating 120 and the functional layer 140 and, on the other hand, the functional layer 140 can be deposited directly under an overblocker coating 150 positioned between the functional layer 140 and the overlying antireflective coating 160.

The underblocker and/or overblocker layers, although deposited in metallic form and presented as being metallic layers, are sometimes in practice oxidized layers since one of their functions (in particular for the overblocker layer) is to become oxidized during the deposition of the stack in order to protect the functional layer.

When a stack is used in a multiple glazing 100 of double glazing structure, as illustrated in FIG. 2, this glazing comprises two substrates 10, 30 which are held together by a frame structure 90 and which are separated from one another by an inserted gas-filled cavity 15.

The glazing thus provides a separation between an external space ES and an internal space IS.

The stack can be positioned on face 3 (on the sheet furthest inside the building when considering the incident direction of the sunlight entering the building and on its face facing the gas-filled cavity).

FIG. 2 illustrates this positioning (the incident direction of the sunlight entering the building being illustrated by the double arrow) on face 3 of a stack of thin layers 14 positioned on an internal face 29 of the substrate 30 in contact with the inserted gas-filled cavity 15, the other face 31 of the substrate 30 being in contact with the internal space IS.

However, it can also be envisaged that, in this double glazing structure, one of the substrates exhibits a laminated structure.

The layers deposited can be classified into three categories:

i—the layers made of antireflective/dielectric material, exhibiting an n/k ratio over the entire wavelength range of the visible region of greater than 5: the layers based on silicon nitride, based on silicon-zirconium nitride, based on zinc oxide, based on zinc tin oxide, based on titanium oxide, based on titanium-zirconium oxide, based on silicon oxide, and the like;

ii—the metallic functional layers made of material having properties of reflection in the infrared region and/or in the solar radiation region: for example based on silver or made of silver: it has been found that silver exhibits a ratio 0<n/k<5 over the entire wavelength range of the visible region, but its electrical resistivity in the bulk state is less than 10⁻⁶ Ω·cm;

iii—underblocker and overblocker layers intended to protect the functional layer from modification to its nature during the deposition of the stack and/or during a heat treatment; the refractive index of these layers is not considered in the optical definition of the stack.

For all the examples below, the names of constituent layer materials denote the following materials, with their refractive index, measured at 550 nm:

TABLE 2

| Name | Material | Stoichiometry | Index |
|---|---|---|---|
| SiN | Silicon nitride doped with | Si₃N₄:Al | 2.10 |
| | aluminum | | |
| ZnO | Zinc oxide | ZnO | 2.00 |
| NiCr | Nickel-chromium alloy | Ni_{0.8}Cr_{0.2} | — |
| SiZrN′ | conventional silicon- | Si_{x′}Zr_{y′}N_{z′} with | 2.12-2.30 |
| | zirconium nitride | 5.0% ≤ y′/(y′ + x′) < 25.0% | |
| SiZrN | Silicon-zirconium nitride | SiₓZr_{y}N_{z} with | 2.31-2.60 |
| | enriched in Zr | 25.0% ≤ y/(y + x) ≤ 40.0% | |
| SiZrN″ | Silicon-zirconium nitride | Si_{x″}Zr_{y″}N_{z″} with | >2.60 |
| | excessively riched in Zr | y″/(y″ + x″) > 40.0% | |
| TiO | Titanium oxide | TiO_{b} | 2.44 |
| TiZrO | Titanium-zirconium oxide | Ti_{c}Zr_{d}O | 2.38 |
| SnZnO | Zinc-tin oxide | SnₑZn_{f}O | 1.95 |
| SiO | Silicon dioxide doped with | SiO₂:Al | 1.55 |
| | aluminum | | |
| Ag | Ag | | — |

This table shows in particular that silicon-zirconium nitride enriched in Zr, on the sixth line, is a material, the refractive index of which is higher than that of silicon nitride doped with aluminum, on the second line, and higher than that of conventional silicon nitride doped with zirconium, on the fifth line.

The refractive index at 550 nm and also the coefficient of absorption at 380 nm, which represents the absorption of the material in the blue region, of silicon-zirconium nitride as a function of the atomic content of Zr with respect to the sum Zr+Si are illustrated respectively in FIGS. 3 and 4. It is considered that the doping with aluminum does not influence this refractive index and this coefficient of absorption.

These FIGS. 3 and 4 show that silicon-zirconium nitride, the Zr/(Zr+Si) atomic ratio of which is between 25.0% and 40.0%, makes it possible to achieve a high refractive index, while exhibiting a low absorption in the blue region, in order to avoid an excessively red appearance in reflection and an excessively yellow appearance in transmission.

In this range from 25.0 to 40.0%, the refractive index is close to that of TiO₂; silicon-zirconium nitride enriched in Zr can thus be substituted for TiO₂; the coefficient of absorption is admittedly higher than that of TiO₂ but this increase is relatively low.

In the range between 27.0% and 37.0%, the refractive index is virtually identical to that of TiO₂ and the coefficient of absorption is very close to 0.1, which is an acceptable value.

A general configuration of a stack of thin layers, in connection with FIG. 1, is presented in table 3 below, with, for the layers, the recommended materials and also the recommended ranges of thicknesses for this general configuration.

TABLE 3

| | | | Thicknesses |
|---|---|---|---|
| Layer No. | Coating | Material | (nm) |
| 168 | 160 | SiN | 25.0-35.0 |
| 166 | | SiZrN | 6.0-12.0 |
| 162 | | ZnO | 3.0-8.0 |
| 150 | | NiCr | 0-1.0 |
| 140 | | Ag | 9.0-16.0 |
| 128 | 120 | ZnO | 3.0-8.0 |
| 126 | | SiZrN | 10.0-30.0 |
| 124 | | SiZrN′ | 0-15.0 |
| 122 | | SiN | 5.0-15.0 |

In this configuration, the two antireflective coatings 120 and 160 each comprise a SiZrN layer based on silicon-zirconium nitride enriched in Zr.

When the stack comprises at least one SiZrN layer based on silicon-zirconium nitride enriched in Zr in each of the two antireflective coatings, in the underlying antireflective coating 120, the layer based on silicon-zirconium nitride enriched in Zr, SiₓZr_{y}N_{z}, can be the sole high-index layer; its optical thickness can then represent between 70.0% (for y/(x+y) close to 25.0%) and 50.0% (for y/(x+y) close to 40.0%) of the optical thickness of the underlying antireflective coating 120.

However, it is possible for this underlying antireflective coating 120 to comprise several high-index layers; in this case, in the underlying antireflective coating 120, the layer based on silicon-zirconium nitride enriched in Zr, SiₓZr_{y}N_{z}, can then represent between 35.0% (for y/(x+y) close to 25.0%) and 25.5% (for y/(x+y) close to 40.0%) of the optical thickness of the underlying antireflective coating 120; it then being possible for the optical thickness of the other high-index layer (such as, for example, a layer made of SiZrN′, based on conventional silicon-zirconium nitride) or the sum of the optical thicknesses of the other high-index layers, in the case where there are several of them, to respectively represent between 35.0% and 25.0% of the optical thickness of the underlying antireflective coating 120.

Another general configuration of a stack of thin layers, in connection with FIG. 1, is presented in table 4 below, with, for the layers, the recommended materials and also the recommended ranges of thicknesses for this general configuration.

TABLE 4

| | | | Thicknesses |
|---|---|---|---|
| Layer No. | Coating | Material | (nm) |
| 168 | 160 | SiN | 5.0-15.0 |
| 162 | | ZnO | 3.0-8.0 |
| 150 | | NiCr | 0-1.0 |
| 140 | | Ag | 9.0-16.0 |
| 128 | 120 | ZnO | 3.0-8.0 |
| 126 | | SiZrN | 10.0-30.0 |
| 124 | | SiZrN′ | 0-15.0 |
| 122 | | SiN | 5.0-15.0 |

In this configuration, only the underlying antireflective coating 120 comprises a SiZrN layer 126 based on silicon-zirconium nitride enriched in Zr; the overlying antireflective coating 160 does not comprise a layer based on silicon-zirconium nitride enriched in Zr.

In this case, the layer based on silicon-zirconium nitride enriched in Zr, SiₓZr_{y}N_{z}, can be the sole high-index layer of the underlying antireflective coating 120; its optical thickness can then represent between 30.0% (for y/(x+y) close to 25.0%) and 60.0% (for y/(x+y) close to 40.0%) of the optical thickness of the underlying antireflective coating 120.

However, it is possible for the underlying antireflective coating 120 to comprise several high-index layers; in this case, the optical thickness of the layer based on silicon-zirconium nitride enriched in Zr, SiₓZr_{y}N_{z}, can then represent between 15.0% (for y/(x+y) close to 25.0%) and 30.0% (for y/(x+y) close to 40.0%) of the optical thickness of the underlying antireflective coating 120; it then being possible for the optical thickness of the other high-index layer (such as, for example, a layer made of SiZrN′, based on conventional silicon-zirconium nitride) or the sum of the optical thicknesses of the other high-index layers, in the case where there are several of them, to respectively represent between 15.0% and 30.0% of the optical thickness of the underlying antireflective coating 120.

For all the examples below, the conditions for deposition of the layers are:

TABLE 5

| | | Deposition | | |
|---|---|---|---|---|
| Layer | Target employed | pressure | | Gas |
| SiN | Si:Al at 92:8 wt % | 1.5 × 10⁻³ | mbar | Ar/(Ar + N₂) at 55% |
| ZnO | Zn:O at 50:50 atom % | 2 × 10⁻³ | mbar | Ar/(Ar + O₂) at 90% |
| NiCr | Ni:Cr at 80:20 atom % | 8 × 10⁻³ | mbar | Ar at 100% |
| SiZrN′ | Si:Zr:Al at 78:17:5 atom % | 2 × 10⁻³ | mbar | Ar/(Ar + N₂) at 45% |
| SiZrN | Si:Zr:Al at 68:27:5 atom % | 2 × 10⁻³ | mbar | Ar/(Ar + N₂) at 45% |
| | or at 58:37:5 atom % | | | |
| SiZrN″ | Si:Zr:Al at 48:47:5 atom % | 2 × 10⁻³ | mbar | Ar/(Ar + N₂) at 45% |
| TiO | TiO₂ | 2 × 10⁻³ | mbar | Ar/(Ar + O₂) at 95% |
| TiZrO | TiZrO₄ | 2 × 10⁻³ | mbar | Ar/(Ar + O₂) at 95% |
| SnZnO | Zn:Sn at 64:36 atom % | 2 × 10⁻³ | mbar | Ar/(Ar + O₂) at 50% |
| SiO₂ | Si:Al at 92:8 wt % | 2 × 10⁻³ | mbar | Ar/(Ar + O₂) at 50% |
| Ag | Ag | 8 × 10⁻³ | mbar | Ar at 100% |

In all the examples below, the stack of thin layers is deposited on a substrate made of clear soda-lime glass with a thickness of 4 mm of the Planiclear brand, distributed by Saint-Gobain.

The physical thicknesses in nanometers of each of the layers or of the coatings of the examples are set out in tables 6, 8, 10 and 11 below and the main data relating to examples 1 to 10 are combined in table 3.

In tables 6, 8, 10 and 11, the “No.” column indicates the number of the layer and the second column indicates the coating, in connection with the configuration of FIG. 1; the third column indicates the material deposited for the layer of the first column, with, for the layers made of “SiZrN”, “SiZrN′” and “SiZrN”, a value in brackets which denotes, for this layer of this example, the Zr/(Zr+Si+Al) atomic ratio, as a percentage.

In tables 7, 9 and 12, the characteristics of the substrate coated with a stack which are presented consist, for each of these examples, after a tempering heat treatment of the coated substrate at 650° C. for 10 minutes, followed by cooling, using the illuminant D65 2° for examples 1 to 5 and the illuminant D65 10° for examples 6 to 18, of the measurement:
for LT, of the luminous transmission in the visible region, in %,
for Ta* and Tb*, of the colors in transmission in the La*b* system,
for LRs, of the luminous reflection in the visible region, in %, stack side,
for Rsa* and Rsb*, of the colors in reflection in the La*b* system, stack side,
for LRg, of the luminous reflection in the visible region, in %, glass side,
for Rga* and Rgb*, of the colors in reflection in the La*b* system, glass side, and
for E, of the emissivity.

For examples 1 to 5, “g” indicates the measurement of the solar factor in a double glazing configuration, consisting of an external substrate made of clear 4-mm glass, of an inserted 16-mm space filled with argon and of an internal substrate made of clear 4-mm glass, with the stack located on face 3, that is to say on the face of the internal substrate facing the inserted space.

For examples 6 to 18, “g” indicates the measurement of the solar factor in a triple glazing configuration, consisting of an external substrate made of clear 4-mm glass, of an inserted 12-mm space filled with argon, of a central substrate made of clear 4-mm glass, of an inserted 12-mm space filled with argon and of an internal substrate made of clear 4-mm glass, with the stack located on face 2 and 5, that is to say on the face of the external substrate and of the internal substrate which is facing the inserted space.

TABLE 6

| | | | Ex. | | | | |
|---|---|---|---|---|---|---|---|
| No. | | | 1 | 2 | 3 | 4 | 5 |
| 168 | 160 | SiN | 42.0 | 28.7 | 30.3 | 32.3 | 36.0 |
| 166 | | SiZrN | — | — | 9.0 (27%) | 6.7 (37%) | — |
| 164 | | SiZrN′ | — | 11.8 (17%) | — | — | 3.8 (47%) |
| | | or | | | | | |
| | | SiZrN″ | | | | | |
| 162 | | ZnO | 5.0 | 5.0 | 5.0 | 5.0 | 5.0 |
| 150 | | NiCr | 1.0 | 1.0 | 1.0 | 1.0 | 1.0 |
| 140 | | Ag | 15.0 | 15.0 | 15.0 | 15.0 | 15.0 |
| 128 | 120 | ZnO | 5.0 | 5.0 | 5.0 | 5.0 | 5.0 |
| 126 | | SiZrN | — | — | 17.5 (27%) | 13.7 (37%) | — |
| 124 | | SiZrN′ | — | 20.8 (17%) | — | — | 8.7 (47%) |
| | | or | | | | | |
| | | SiZrN″ | | | | | |
| 122 | | SiN | 28.6 | 5.0 | 5.0 | 9.0 | 15.3 |

TABLE 7

| Ex. | 1 | 2 | 3 | 4 | 5 |
|---|---|---|---|---|---|
| LT | 78.3 | 80.9 | 72.4 | 82.8 | 81.9 |
| Ta* | −1.3 | −1.2 | −1.3 | −1.5 | −1.5 |
| Tb* | 5.1 | 4.6 | 4.9 | 5.2 | 5.7 |
| LRs | 13.3 | 10.6 | 8.4 | 7.8 | 8.3 |
| Rsa* | 2.9 | 2.6 | 2.4 | 2.2 | 2.3 |
| Rsb* | −14.8 | −14.2 | −12.1 | −10.2 | −9.5 |
| LRg | 16.2 | 13.3 | 11.1 | 10.5 | 11.2 |
| Rga* | 1.4 | 0.7 | −0.5 | −0.9 | −1.0 |
| Rgb* | −12.5 | −11.2 | −8.0 | −6.2 | −5.8 |
| E (%) | 2.2 | 2.2 | 2.2 | 2.2 | 2.2 |
| g (%) | 55.4 | 57.1 | 58.5 | 58.8 | 58.8 |

In the first series of examples, that of tables 6 and 7, example 1 constitutes a base example of the technology of silver monolayer low-e stacks comprising barrier layers, as disclosed in the patent application EP 718 250: the functional layer 140 made of silver is deposited directly on a wetting layer 128 made of zinc oxide and an overblocker layer 150 made of NiCr is provided immediately over this functional layer 140, followed by another layer 162 made of zinc oxide. This assembly is framed by a lower barrier layer 122, based on silicon nitride, and an upper barrier layer 168, also based on silicon nitride.

This example 1 exhibits a high luminous transmission LT, of the order of 78%, and a low emissivity E, of the order of 2%; its solar factor, g, as double glazing, is moderate, of the order of 55%, and some colorimetric data are satisfactory in the sense that, in particular, Tb* is close to 5.0, which implies a color in transmission which is not too yellow; on the other hand, one colorimetric datum is not satisfactory: Rsa* is too high, which implies a color in reflection on the stack side which is too red.

Example 2 constitutes an improvement in the base technology of example 1 as the luminous transmission LT is increased, which results in an increase in the solar factor in the same double glazing configuration. Of course, the emissivity is retained since the functional layer exhibits the same thickness and is framed directly by the same layers. Tb* is close to 5.0, which is satisfactory, and Rsa* is close to 2.5, which is also satisfactory.

This is obtained because, on the one hand, a portion of the lower barrier layer 122 is replaced with a high-index and barrier layer 124 and, on the other hand, a portion of the upper barrier layer 168 is replaced with a high-index and barrier layer 164.

This example 2 is capable of improvement in the sense that, if the luminous transmission were to be very high, of the order of 82% or more, then the solar factor might be even higher.

Example 3 constitutes an improvement owing to the fact that the very high luminous transmission makes it possible to achieve a high solar factor, of greater than 58%. The emissivity is, of course, retained and the colorimetric data are satisfactory as Tb* is close to 5.0 and Rsa* is close to 2.5.

Example 4 also constitutes an improvement owing to the fact that the very high luminous transmission, even higher than that of example 3, makes it possible to achieve a solar factor close to 59%. The emissivity is, of course, retained and the colorimetric data are satisfactory as Tb* is close to 5.0 and Rsa* is close to 2.5.

Example 5 does not constitute an improvement with respect to example 4 as it exhibits a lower luminous transmission and a lower solar factor.

Example 5 does not constitute an improvement with respect to example 2 because, even though it exhibits a very high luminous transmission and makes it possible to achieve a high solar factor, Tb* is too far from 5.0.

In a second series of examples, the reference example, No. 6, is chosen to be similar to example 1 of the first series, with the same layer sequence, but with a thinner functional layer than for the first series.

TABLE 8

| | | | Ex. | | | | |
|---|---|---|---|---|---|---|---|
| No. | | | 6 | 7 | 8 | 9 | 10 |
| 168 | 160 | Si₃N₄ | 35.0 | 37.0 | 38.8 | 38.8 | 38.0 |
| 162 | | ZnO | 5.0 | 5.0 | 5.0 | 5.0 | 5.0 |
| 150 | | NiCr | 1.0 | 1.0 | 1.0 | 1.0 | 1.0 |
| 140 | | Ag | 9.8 | 9.8 | 9.8 | 9.8 | 9.8 |
| 128 | 120 | ZnO | 5.0 | 5.0 | 5.0 | 5.0 | 5.0 |
| 126 | | SiZrN | — | — | 19.4 (27%) | 13.6 (37%) | — |
| 124 | | SiZrN′ | — | 29.2 (17%) | — | — | 8.7 (47%) |
| | | or | | | | | |
| | | SiZrN″ | | | | | |
| 122 | | Si₃N₄ | 34.4 | 5.4 | 16.0 | 24.4 | 31.1 |

TABLE 9

| Ex. | 6 | 7 | 8 | 9 | 10 |
|---|---|---|---|---|---|
| LT | 88.6 | 89.2 | 88.9 | 88.9 | 88.7 |
| Ta* | −0.9 | −1.0 | −1.1 | −1.3 | −1.2 |
| Tb* | 2.0 | 1.6 | 2.2 | 2.5 | 2.8 |
| LRs | 4.7 | 4.5 | 4.6 | 4.6 | 4.5 |
| Rsa* | 2.6 | 2.1 | 2.0 | 1.9 | 1.9 |
| Rsb* | −12.0 | 7.8 | −6.5 | −6.2 | −6.0 |
| LRg | 5.9 | 5.3 | 5.5 | 5.4 | 5.4 |
| Rga* | 1.7 | 0.9 | −0.5 | −0.5 | −0.3 |
| Rgb* | −12.9 | −8.2 | −5.0 | −5.1 | −6.1 |
| E (%) | 4.2 | 4.2 | 4.2 | 4.2 | 4.2 |
| g (%) | 55.8 | 57.1 | 57.5 | 57.4 | 57.2 |

In the second series of examples, that of tables 8 and 9, example 6 exhibits a high luminous transmission LT and a low emissivity E; the solar factor, g, as triple glazing with two stacks according to the example, one on face 2 and the other on face 5, is moderate, of the order of 55%, and some colorimetric data are satisfactory in the sense that, in particular, Tb* is close to 2.0, which implies a color in transmission which is not too yellow; on the other hand, one colorimetric datum is not satisfactory: Rsa* is too high, which implies a color in reflection on the stack side which is too red.

Example 7 constitutes an improvement in the technology of example 6 as the luminous transmission LT is increased, which results in an increase in the solar factor in the same triple glazing configuration. Of course, the emissivity is retained since the functional layer exhibits the same thickness and is framed directly by the same layers. Tb* decreases, which is satisfactory, and Rsa* is close to 2.0, which is also satisfactory.

This is obtained owing to the fact that a portion of the lower barrier layer 122 is replaced with a high-index and barrier layer 124.

This example 7 is capable of improvement in the sense that the solar factor might be even higher.

Example 8 constitutes an improvement owing to the fact that the luminous transmission is higher than that of example 6; it is not as high as that of example 7 but makes it possible to achieve a greater solar factor than that of example 7. The emissivity is, of course, retained and the colorimetric data are satisfactory as Tb* is close to 2.0 and Rsa* is close to 2.0.

Example 9 also constitutes an improvement with respect to examples 6 and 7 owing to the fact that the luminous transmission is as high as that of example 8 and that the solar factor is as high as that of example 8. The emissivity is, of course, retained and the colorimetric data are satisfactory as Tb* is close to 2.0, even if it has moved away from it in comparison with example 8, and Rsa* is close to 2.0.

Example 10 does not constitute an improvement with respect to example 9 as it exhibits a lower luminous transmission and a lower solar factor.

Example 10 does not constitute an improvement with respect to example 7 because, even though it exhibits a high luminous transmission, Tb* is too far away from the value of 2.0 obtained with example 6.

TABLE 10

| | | | Ex. | | | | |
|---|---|---|---|---|---|---|---|
| No. | | | 3 | 11 | 12 | 13 | 14 |
| 168 | 160 | SiN | 30.3 | 30.3 | 30.0 | 30.0 | 18.0 |
| 166 | | SiZrN | 9.0 (27%) | — | — | — | — |
| 164 | | SiZrN″ | — | 9.0 (47%) | — | — | — |
| | | TiOₓ | — | — | 9.0 | — | — |
| | | TiZrOₓ | — | — | — | 9.0 | — |
| 163 | | SnZnO | — | — | — | — | 22.0 |
| 162 | | ZnO | 5.0 | 5.0 | 5.0 | 5.0 | 5.0 |
| 150 | | NiCr | 1.0 | 1.0 | 1.0 | 1.0 | — |
| 140 | | Ag | 15.0 | 15.0 | 15.0 | 15.0 | 15.0 |
| 128 | 120 | ZnO | 5.0 | 5.0 | 5.0 | 5.0 | 5.0 |
| 126 | | SiZrN | 17.5 (27%) | — | — | — | — |
| 124 | | TiOₓ | — | 18.0 | 18.0 | — | — |
| | | TiZrOₓ | — | — | — | 18.0 | 19.0 |
| 123 | | SnZnO | — | — | — | — | 10.0 |
| 122 | | SiN | 5.0 | 15.3 | 15.3 | 15.3 | — |

In the third series of examples, that of table 10, the preceding example 3 is taken as reference and examples 11 to 14 have been designed in order to obtain the same optical properties after heat treatment as this example 3; this is the reason why these data are not shown.

Example 14 is an example based on the teaching of international patent application No. WO 2014/191472.

Examples 11 to 14 do not withstand the heat treatment of 650° C. for 10 minutes: example 11 exhibits numerous large defects, with star-shaped blemishes with a width of the order of 0.5 micron; example 12 exhibits a very significant haze and a great many fine defects, of the order of 0.1 micron; examples 13 and 14 do not exhibit a haze but a great many fine defects, of the order of 0.1 micron; only example 3 is devoid of large defects, of fine defects and of haze.

TABLE 11

| | | | Ex. | | | | |
|---|---|---|---|---|---|---|---|
| No. | | | 7 | 15 | 16 | 17 | 18 |
| 169 | 160 | SiO | — | 30.0 | 30.0 | 30.0 | 30.0 |
| 168 | | Si₃N₄ | 37.0 | 26.4 | 27.1 | 13.1 | 13.0 |
| 166 | | SiZrN | — | — | — | — | 13.0 (27%) |
| 164 | | SiZrN′ | — | — | — | 13.0 (17%) | — |
| 162 | | ZnO | 5.0 | 5.0 | 5.0 | 5.0 | 5.0 |
| 150 | | NiCr | 1.0 | 1.0 | 1.0 | 1.0 | 1.0 |
| 140 | | Ag | 9.8 | 9.8 | 9.8 | 9.8 | 9.8 |
| 128 | 120 | ZnO | 5.0 | 5.0 | 5.0 | 5.0 | 5.0 |
| 126 | | SiZrN | — | — | 19.1 (27%) | — | 21.1 (27%) |
| 124 | | SiZrN′ | 29.2 (17%) | 19.6 (17%) | — | 21.5 (17%) | — |
| 122 | | Si₃N₄ | 5.4 | 15.5 | 14.0 | 16.4 | 15.0 |

TABLE 12

| Ex. | 7 | 15 | 16 | 17 | 18 |
|---|---|---|---|---|---|
| LT | 89.2 | 88.8 | 89.2 | 89.0 | 89.3 |
| Ta* | −1.0 | −1.2 | −1.4 | −1.4 | −1.8 |
| Tb* | 1.6 | 1.7 | 1.9 | 2.4 | 2.7 |
| LRs | 4.5 | 4.6 | 4.4 | 4.7 | 4.7 |
| Rsa* | 2.1 | 2.1 | 2.0 | 2.0 | 2.0 |
| Rsb* | 7.8 | −8.3 | −7.1 | −9.4 | −6.8 |
| LRg | 5.3 | 5.9 | 5.5 | 5.9 | 5.7 |
| Rga* | 0.9 | 0.7 | 0.4 | 1.2 | 1.0 |
| Rgb* | −8.2 | −6.5 | −4.4 | −8.7 | −6.6 |
| E (%) | 4.2 | 4.2 | 4.2 | 4.2 | 4.2 |
| g (%) | 57.1 | 57.4 | 58.1 | 57.9 | 58.7 |

In the fourth series of examples, that of tables 11 and 12, the preceding example 7 is taken as reference. Examples 15 and 17 each correspond to an improvement in this example 7 with the insertion, into the dielectric coating overlying the functional layer 140, of a layer made of dielectric material of low index, the layer 169, made of SiO. In addition, for example 17, the dielectric coating overlying the functional layer 140 comprises a layer made of dielectric material of high index, the layer 164, made of SiZrN′, that is to say made of conventional silicon-zirconium nitride.

The layer 169 contributes to a higher solar factor being obtained; as seen in table 12, example 15 exhibits a solar factor, g, increased by 0.3% in triple glazing configuration as explained above, with respect to that of example 7, and example 17 exhibits a solar factor, g, increased by 0.8% in triple glazing configuration as explained above, with respect to that of example 7.

Example 16 constitutes an example according to the invention and an improvement in example 15: the replacement of the dielectric material of the layer of high index, the layer 126, made of SiZrN′, with a dielectric material layer of higher index, the layer 128, made of SiZrN, that is to say made of silicon-zirconium nitride enriched in Zr, makes it possible to further increase the solar factor, by 0.7% with respect to that of example 15, in the same triple glazing configuration, by virtue of obtaining a very high luminous transmission, which is found to be that of example 7.

Example 18 constitutes an example according to the invention and an improvement in example 17: the replacement of the dielectric material layer of high index, the layer 164, made of SiZrN′, with a dielectric material layer of higher index, the layer 166, made of SiZrN, that is to say made of silicon-zirconium nitride enriched in Zr, makes it possible to further increase the solar factor, by 0.8% with respect to that of example 17, in the same triple glazing configuration, by virtue of obtaining a very high luminous transmission.

Examples 15 to 18 have been configured with a low-index dielectric layer, the layer 169, which exhibits a thickness of 30 nm; this thickness constitutes a favorable choice between the desired effect of improving the solar factor and the ease of deposition of this layer. Other solutions are acceptable with a thickness of this low-index dielectric layer of between 15.0 and 60.0 nm. The choice of a thickness of this low-index dielectric layer of 55.0 nm results, for example, in the solar factor being further increased by 0.3%.

Furthermore, tables 7, 9 and 12 show that the examples exhibit optical characteristics which are acceptable from the viewpoint of expectations and in particular a low coloration, both in transmission and in reflection, on the stack side or on the glass side, and also a low luminous reflection in the visible region, both on the stack side LRs and on the glass side LRg.

Tests have furthermore been carried out with targets of 68.0 atom % to 66.0 atom % of Si per 27.0 atom % to 29.0 atom % of Zr with 5 atom % of Al in all cases, which corresponds to a range of atomic ratio of Zr to the sum Al+Si+Zr, y/(w+x+y), between 27.0% and 29.0%, these values being incorporated; these targets being sputtered in a nitrogen-containing atmosphere.

These tests have made it possible to obtain layers with refractive indices at 550 nm between 2.37 and 2.42, these values being incorporated, which is particularly favorable.

As a result of the low sheet resistance obtained and also of the good optical properties (in particular the luminous transmission in the visible region), it is furthermore possible to use the substrate coated with the stack according to the invention to produce a transparent electrode substrate.

Generally, the transparent electrode substrate may be suitable for a heated glazing, for an electrochromic glazing, for a display screen, or also for a photovoltaic cell (or panel) and in particular for a transparent photovoltaic cell backsheet.

The present invention is described in the preceding text by way of example. It is understood that a person skilled in the art is able to produce different alternative forms of the invention without, however, departing from the scope of the patent as defined by the claims.

1. A transparent substrate comprising, on a main face, a stack of thin layers comprising a single metallic functional layer having properties of reflection in the infrared region and/or in the solar radiation region, and two antireflective coatings, said antireflective coatings each comprising at least one dielectric layer, said functional layer being positioned between the two antireflective coatings, wherein at least the antireflective coating located between said substrate and said functional layer comprise(s) a layer comprising silicon-zirconium nitride, SiₓZr_{y}N_{z}, with an atomic ratio of Zr to the sum Si+Zr, y/(x+y), which is between 25.0% and 40.0%, these values being incorporated.

2. The substrate as claimed in claim 1, wherein said layer comprising silicon-zirconium nitride, SiₓZr_{y}N_{z}, exhibits a nitridation z of between 4/3(x+y) and 5/3(x+y), these values being incorporated.

3. The substrate as claimed in claim 1, wherein said layer comprising silicon-zirconium nitride, SiₓZr_{y}N_{z}, does not comprise oxygen.

4. The substrate as claimed in claim 1, wherein the antireflective coating located between said substrate additionally comprises a layer comprising zirconium-free silicon nitride.

5. The substrate as claimed in claim 4, wherein said layer comprising zirconium-free silicon nitride exhibits a thickness of between 5.0 and 25.0 nm, these values being included.

6. The substrate as claimed in claim 1, wherein the antireflective coating located above said functional layer on the opposite side from said substrate additionally comprises a layer comprising zirconium-free silicon nitride.

7. The substrate as claimed in claim 6, wherein said layer comprising zirconium-free silicon nitride exhibits a thickness of between 25.0 and 35.0 nm, these values being included.

8. The substrate as claimed in claim 1, wherein the antireflective coating located above said functional layer and on the opposite side from said substrate additionally comprises a layer made of a dielectric material having a low index.

9. The substrate as claimed in claim 1, wherein a layer based on zinc oxide is located below and in contact with said functional layer.

10. The substrate as claimed in claim 1, wherein said layer comprising silicon-zirconium nitride, SiₓZr_{y}N_{z}, which is located between said substrate and said functional layer, exhibits a thickness of between 10.0 and 30.0 nm, these values being included.

11. The substrate as claimed in claim 1, wherein said layer comprising silicon-zirconium nitride, SiₓZr_{y}N₇, which is located above said functional layer on the opposite side from said substrate 44 exhibits a thickness of between 6.0 and 12.0 nm, these values being included.

12. A glazing comprising at least one substrate as claimed in claim 1.

13. The glazing as claimed in claim 12, mounted as a monolithic unit or as a multiple glazing unit of the double glazing or triple glazing or laminated glazing type, wherein at least the substrate carrying the stack is bent and/or tempered.

14. The substrate as claimed in claim 1, wherein the substrate is produced in a transparent electrode of a heated glazing or of an electrochromic glazing or of a lighting device or of a display device or of a photovoltaic panel.

15. A process for the manufacture of the substrate as claimed in claim 1, comprising manufacturing said layer comprising silicon-zirconium nitride, SiₓZr_{y}N₇, by sputtering, in a nitrogen-comprising atmosphere, a target comprising an atomic ratio of Zr to the sum Si+Zr, y/(x+y), which is between 25.0% and 40.0%, these values being incorporated.

16. The process as claimed in claim 15, wherein said atmosphere does not comprise oxygen.

17. A target for the implementation of the process as claimed in claim 15, comprising an atomic ratio of Zr to the sum Si+Zr, y/(x+y), which is between 25.0% and 40.0%, these values being incorporated.

18. The substrate as claimed in claim 1, wherein the single metallic functional layer having properties of reflection in the infrared region and/or in the solar radiation region is based on silver or on silver-containing metal alloy.

19. The substrate as claimed in claim 1, wherein both of the antireflective coatings comprise the layer comprising silicon-zirconium nitride, SiₓZr_{y}N_{z}, with an atomic ratio of Zr to the sum Si+Zr, y/(x+y), which is between 25.0% and 40.0%, these values being incorporated

20. The substrate as claimed in claim 1, wherein the atomic ratio of Zr to the sum Si+Zr, y/(x+y), is between 27.0% and 37.0%, these values being incorporated
